(19) United States
(12) Patent Application Publication
(10) Pub. No.: US 2017/0200767 A1
(43) Pub. Date: Jul. 13, 2017

(54) MAGNETIC ELEMENT AND METHOD OF FABRICATION THEREOF

(71) Applicant: AGENCY FOR SCIENCE, TECHNOLOGY AND RESEARCH, Singapore (SG)

(72) Inventor: Guchang HAN, Singapore (SG)

(21) Appl. No.: 15/510,679

(22) PCT Filed: Sep. 14, 2015
(86) PCT No.: PCT/SG2015/050315

§ 371 Date: Mar. 11, 2017

(30) Foreign Application Priority Data
Sep. 11, 2014 (SG) 10201405641P

(51) Int. Cl. H01L 27/24; H01F 10/32; G11C 11/16; H01L 43/08; H01L 43/12

(52) U.S. Cl. CPC H01L 27/2436; H01L 43/08; H01L 43/12; G11C 11/161; H01F 10/3254

(57) ABSTRACT

There is provided a magnetic element including a reference layer made of a ferromagnetic material and having a fixed or pinned magnetization direction, a free layer made of a ferromagnetic material and having a switchable magnetization direction based spin transfer torque, and a spacer layer disposed between the reference layer and the free layer. In particular, the free layer includes a surface facing away from the spacer layer, and the magnetic element further includes a current confined layer disposed on the above-mentioned surface of the free layer. The current confined layer including at least one conductive channel extending through the current confined layer for concentrating current to flow through the at least one conductive channel. There is also provided a corresponding method of fabricating such a magnetic element and a magnetic memory device including an array of such magnetic elements.

### CROSS-REFERENCE TO RELATED APPLICATION

This application claims the benefit of priority of Singapore Patent Application No. 10201405641P, filed 11 Sep. 2014, the contents of which being hereby incorporated by reference in its entirety for all purposes.

### TECHNICAL FIELD

The present invention generally relates to a magnetic element and a method of fabrication thereof, and more particularly, to a spin current driven magnetic element for a magnetic memory device, such as a Spin Transfer Torque Magnetic Random Access Memory (STT-MRAM) device.

### BACKGROUND

Magnetic Random Access Memory (MRAM) has the potential to be the next generation storage device because of its unique advantages, such as nonvolatility, radiation hardness, high density, fast speed, and unlimited endurance. Both magnetic field driven and spin current driven MRAMs have been previously disclosed. Spin Transfer Torque (STT) MRAM uses spin-polarized electrons to switch the magnetization direction of the storage layer (free layer). On the other hand, magnetic field-driven MRAM uses magnetic field generated by the currents passing through the bit line and word line to change the magnetization of the free layer. Compared with the magnetic field-driven MRAM, STT-MRAM has advantages in, for example, scalability, reliability, simplified structure and power consumption.

FIG. 1 shows a conventional magnetic element 100 for a STT-MRAM device. The magnetic element 100 includes a reference layer 102, a free layer 104 and a spacer layer 106 disposed between the reference layer 102 and the free layer 104. The magnetic element 100 may further include an antiferromagnetic (AFM) layer 110, a pinned layer 112, an AFM coupling layer 114, and a capping layer 116 arranged in the manner as shown in FIG. 1. The arrows in each ferromagnetic layer represent the possible magnetization directions thereof. In particular, the magnetization direction can be either in-plane (as illustrated by the arrows on the left side of the layer) or perpendicular to the plane (as shown by the arrows on the right side of the layers).

The magnetization of the free layer 104 can be switched/reversed so that the magnetization of the reference layer 102 and the free layer 104 can be substantially aligned in either a parallel or an antiparallel manner. The resistance of the magnetic element 100 will be low when their magnetization is aligned parallel and will be high when their magnetization is antiparallel. This variation in the resistance of the magnetic element 100 can thus be used to indicate the state of the magnetic element 100 and therefore store data. For example, data “0 ” may correspond to a low resistance state while data “1 ” may correspond to a high resistance state. When a write current (I) passes through the magnetic element 100 as shown in FIG. 1, the magnetization of the free layer 104 can be switched or kept, depending on the direction of the spin angular momentum of the electrons incident on the free layer 104. As a result, the resistance state of the magnetic element 100 can be changed by passing through a sufficiently high current due to the spin transfer torque effect.

However, one of the challenges in the implementation of conventional magnetic element for STT-MRAM application is that the current density required to switch the free layer is too high, typically larger than 10⁶ A/cm². High switching current (denoted as Jc) will not only consume high power, but also limit the scaling of the magnetic memory size due to the requirement of a large transistor for cell selection. The main issue is the low current switching efficiency in the conventional uniform current operational technique applied. In this conventional technique, the current uniformly flows through the magnetic element, therefore, the spin transfer torque needs to be sufficiently high in order to switch the magnetization of the entire free layer simultaneously. Thus, an undesirably high writing current is required.

Conventionally, a non-uniform current has been utilized to enhance the current switching efficiency through the use of a current confined layer (CCL) which is either incorporated into the free layer or disposed between the free layer and the pinned layer. However, the manner in which the current confined layer is implemented/utilized in such conventional techniques unavoidably negatively affects the performances of the magnetic element. For example, in the case of the current confined layer being inserted between the free layer and the reference layer of a tunnel magnetoresistance (TMR) memory device, the TMR will be significantly reduced due to the signal shunting by the conductive channels. On the other hand, in the case of the current confined layer being inserted into the free layer, the crystalline structure of the free layer will deteriorate, thus resulting in the free layer having poor magnetic properties.

A need therefore exists to provide a magnetic element based on spin transfer torque that seeks to overcome, or at least ameliorate, one or more of the deficiencies of conventional magnetic elements, and in particular, to reduce the writing current required to switch the magnetization of the free layer of the magnetic element without undesirably affecting the performances of the magnetic element. It is against this background that the present invention has been developed.

### SUMMARY

According to a first aspect of the present invention, there is provided a magnetic element comprising:
a reference layer made of a ferromagnetic material and having a fixed or pinned magnetization direction;
a free layer made of a ferromagnetic material and having a switchable magnetization direction based spin transfer torque;
a spacer layer disposed between the reference layer and the free layer,
wherein the free layer comprises a surface facing away from the spacer layer, and
the magnetic element further comprises a current confined layer disposed on said surface of the free layer, the current confined layer comprising at least one conductive channel extending through the current confined layer for concentrating current to flow through the at least one conductive channel.

In various embodiments, said at least one conductive channel comprises a plurality of conductive channels extending through the current confined layer

In various embodiments, the current confined layer comprises an insulating matrix, and said at least one conductive channel is formed through the insulating matrix.

In various embodiments, the spacer layer is non-magnetic and comprises a conductive material, and wherein the free layer, the spacer layer, and the reference layer are configured to function as a spin valve.

In various embodiments, the spacer layer is non-magnetic and comprises a non-conductive insulating material, and wherein the free layer, the spacer layer, and the reference layer are configured to function as a magnetic tunnel junction.

In various embodiments, the current confined layer is disposed directly on said surface of the free layer.

In various embodiments, a performance enhancement layer is disposed on the current confined layer for enhancing the performance of the magnetic element.

In various embodiments, the performance enhancement layer is a conductive tuning layer for tuning the performance of the magnetic element or a field cancellation layer for providing offset field control.

In various embodiments, the performance enhancement layer further serves as a protection layer for protecting the free layer when the current confined layer is being formed on the free layer.

In various embodiments, the magnetic element further comprises a capping layer disposed on the current confined layer, wherein the capping layer and the free layer are conductively coupled through said at least one conductive channel of the current confined layer.

According to a second aspect of the present invention, there is provided a method of fabricating a magnetic element, the method comprising:
forming a reference layer made of a ferromagnetic material and having a fixed or pinned magnetization direction;
forming a free layer made of a ferromagnetic material and having a switchable magnetization direction based spin transfer torque;
forming a spacer layer between the reference layer and the free layer,
wherein the free layer comprises a surface facing away from the spacer layer, and
the method further comprises forming a current confined layer on said surface of the free layer, the current confined layer comprising at least one conductive channel extending through the current confined layer for concentrating current to flow through the at least one conductive channel.

In various embodiments, said at least one conductive channel comprises a plurality of conductive channels extending through the current confined layer

In various embodiments, the current confined layer comprises an insulating matrix, and said at least one conductive channel is formed through the insulating matrix.

In various embodiments, said forming a current confined layer comprises forming the current confined layer directly on the second surface of the free layer.

In various embodiments, the method further comprises forming a performance enhancement layer on the current confined layer for enhancing the performance of the magnetic element.

In various embodiments, the performance enhancement layer is a conductive tuning layer for tuning the performance of the magnetic element or a field cancellation layer for providing offset field control.

In various embodiments, the performance enhancement layer further serves as a protection layer for protecting the free layer when the current confined layer is being formed on the free layer.

In various embodiments, the method further comprises forming a capping layer on the current confined layer, wherein the capping layer and the free layer are conductively coupled through said at least one conductive channel of the current confined layer.

According to a third aspect of the present invention, a magnetic memory device comprising an array of magnetic elements, wherein each magnetic element comprising:
a reference layer made of a ferromagnetic material and having a fixed or pinned magnetization direction;
a free layer made of a ferromagnetic material and having a switchable magnetization direction based spin transfer torque;
a spacer layer disposed between the reference layer and the free layer,
wherein the free layer comprises a surface facing away from the spacer layer, and
the magnetic element further comprises a current confined layer disposed on said surface of the free layer, the current confined layer comprising at least one conductive channel extending through the current confined layer for concentrating current to flow through the at least one conductive channel.

### BRIEF DESCRIPTION OF THE DRAWINGS

Embodiments of the present invention will be better understood and readily apparent to one of ordinary skill in the art from the following written description, by way of example only, and in conjunction with the drawings, in which:

FIG. 1 depicts a schematic drawing of a conventional magnetic element;

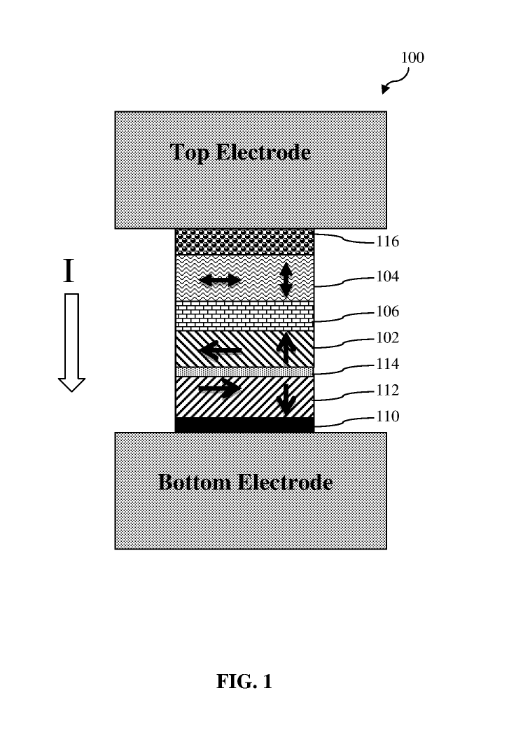

FIG. 2 depicts a schematic drawing of a magnetic element according to an embodiment of the present invention;

FIG. 3 depicts a schematic drawing of an exemplary magnetic element according to a first example embodiment of the present invention;

FIG. 4 depicts a schematic drawing of an exemplary magnetic element according to a second example embodiment of the present invention;

FIG. 5 depicts a schematic drawing of an exemplary magnetic element according to a third example embodiment of the present invention;

FIG. 6 depicts a schematic drawing of an exemplary magnetic element according to a fourth example embodiment of the present invention;

FIG. 7 depicts a schematic flow diagram of a method of fabricating a magnetic element according to an embodiment of the present invention; and

FIG. 8 depicts a magnetic memory device including an array of magnetic elements according to an example embodiment of the present invention.

### DETAILED DESCRIPTION

Embodiments of the present invention provide a magnetic element for a magnetic memory device (such as a STT-MRAM device) that seeks to overcome, or at least ameliorate, one or more of the deficiencies of conventional magnetic elements. As described in the background, a problem associated with conventional spin current driven magnetic element is that a large write current is required to switch the magnetization of the free layer in order to write data to the magnetic element. For example, in a conventional approach which applies a uniform current through the magnetic element (in particular, through the free layer), the write current has to be sufficiently large in order to switch the magnetization of the entire free layer simultaneously. This result in the need for an undesirably large write current to achieve spin transfer switching of the free layer, and thus such a magnetic element has poor current switching efficiency.

According to embodiments of the present invention, the problem of requiring an undesirably large write current to achieve spin transfer switching of the free layer is advantageously addressed (i.e., the required write current can be significantly reduced) without undesirably affecting (e.g., causing a negative impact on) the performances of the magnetic element, such as TMR, thermal stability, endurance, and so on. This is achieved in the embodiments by forming a current confined layer (CCL) on a surface of the free layer facing away from the spacer layer. Therefore, the current confined layer is advantageously positioned outside of the core region formed by the free layer, the space layer and the reference layer (that is, outside the magnetic tunnel junction (MTJ) or spin valve region). With this configuration, the present inventor found that the current confined layer is advantageously able to function as a current filtration without negatively affecting the performances of the magnetic element. Without wishing to be bound by theory, but an explanation is that since the main performances of the magnetic element are determined by the MTJ or spin valve region, positioning the current confined layer outside of such a core region avoids interfering with the performances of such a core region and thus the performances of the magnetic element.

In embodiments, the current confined layer comprises at least one conductive channel extending through the current confined layer for concentrating current to flow through the at least one conductive channel. In a preferred embodiment, the current confined layer comprises an insulating matrix and the at least one conductive channel is formed through the insulating matrix. By providing the current confined layer on the above-mentioned surface of the free layer, the current is thus concentrated to flow through the conductive channel(s), thereby resulting in substantially higher localized current density in portion(s)/regions(s) of the free layer (than the overall current density across the entire free layer if the current applied to the free layer was uniform across the entire free layer) opposing the conductive channel(s). As a result, the magnetization of portion(s) of the free layer opposing the conductive channel(s) will be able to switch first due to the higher localized current density (which exceeds the required critical switching current density), despite the significantly lower overall current density across the entire free layer (which may for example be lower than the required critical switching current density). The localized switching of the magnetization at the above-mentioned portion(s) of the free layer will then in turn induce the switching of other portions of the free layer (i.e., the portions not opposing the conductive channel(s)) due to the strong exchange interaction, thereby switching the magnetization of the entire free layer. Accordingly, the magnetization of the entire free layer can be successfully switched by spin transfer torque using a significantly lower overall writing current, without undesirably affecting the performances of the memory element as discussed hereinbefore.

The magnetization of the free layer can thus be switched/reversed using spin transfer torque so that the magnetization of the reference layer and the free layer can be substantially aligned in either a parallel or an antiparallel manner. The resistance of the magnetic element will be low when their magnetization is aligned parallel and will be high when their magnetization is antiparallel. This variation in the resistance of the magnetic element can thus be used to indicate the state of the magnetic element and therefore store data. For example, data “0” may correspond to a low resistance state while data “1” may correspond to a high resistance state. When a write current (I) passes through the magnetic element, the magnetization of the free layer can be switched or maintained, depending on the direction of the spin angular momentum of the electrons incident on the free layer.

Throughout the present specification, it can be understood that when a layer or element is referred to as being “on” another layer or element, the layer or element can be directly on another layer or element (i.e., without any intermediate/intervening layers or elements therebetween) or indirectly on another layer or element (i.e., with one or more intermediate layers or elements therebetween). Therefore, unless stated otherwise, such an expression should be interpreted to cover both cases.

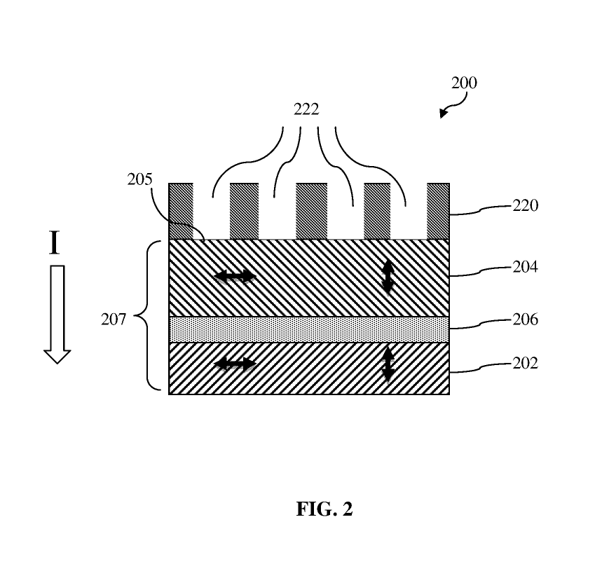

FIG. 2 depicts a schematic drawing of a magnetic element 200 according to an embodiment of the present invention. The magnetic element 200 comprises a reference layer 202 made of a ferromagnetic material and having a fixed or pinned magnetization direction, a free layer 204 made of a ferromagnetic material and having a switchable magnetization direction based spin transfer torque, and a spacer layer 206 disposed between the reference layer 202 and the free layer 204. In particular, the free layer 204 comprises a surface 205 facing away from the spacer layer 206, and the magnetic element 200 further comprises a current confined layer 220 disposed on the above-mentioned surface of the free layer 204. Therefore, the current confined layer 220 is advantageously positioned outside of the core region 207 formed by the free layer 204, the space layer 206 and the reference layer 202 (that is, the MTJ or spin-valve region). The current confined layer 220 comprises at least one conductive channel 222 extending through the current confined layer 220 for concentrating current to flow through the at least one conductive channel 222.

With the above-described configuration of the magnetic element 200, in operation, the current applied to the magnetic element 200 will be concentrated to flow through the conductive channel(s) 222 of the current confined layer 220. Therefore, as described hereinbefore, the localized current density of portion(s) of the free layer 204 opposing the conductive channel(s) 222 will be substantially larger than other portion(s) of the free layer 204 not opposing the conductive channel(s) 222. When this localized current density exceeds the critical switching current density (Jc), the localized magnetization of portion(s) of the free layer 204 opposing the conductive channel(s) will be caused to switch first, and then in turn induce the switching of the entire free layer 204 due to the exchange coupling.

Without wishing to be bound by theory, but as an example, suppose the conductive channel(s) occupies a cross-sectional area denoted as “A” over an entire planar cross-sectional area of the free layer 204 denoted as “B”, the write current reduction can be derived to be:

$${J}_{c} \times \frac{A}{B} , \qquad ( 1 )$$

where Jc is the switching current density in the case of uniform current flowing through the magnetic element. Therefore, from Equation (1), it can be understood that the required write current is based on the ratio between areas “A” and “B”, and can be adjusted/tuned by configuring/setting the area and number of the conductive channel(s) 222 accordingly. For example, if for the current confined layer 220, the area “A” is configured to be 10% of the area “B”, the required write current using the current confined layer may be significantly reduced to about 10% of the write current required by applying the conventional uniform current flow technique. By way of example and without limitations, a suitable configuration includes a current confined layer 220 in which low resistivity paths exist with conductive channels 222 having a diameter of a few angstroms or more, e.g., about 1 to 10 angstroms, uniformly distributed across the planar surface of the current confined layer 220 so as not to add a large parasitic resistance.

In an embodiment, the current confined layer 220 may comprise a plurality of conductive channels 222 extending through the current confined layer 220. Preferably, the current confined layer 220 comprises an insulating matrix 224 and the conductive channel(s) 222 are formed through the insulating matrix 224 as for example illustrated in FIG. 2. For example and without limitation, the insulating matrix 224 can be made of any insulators (such as MgO, AlOx, SiOx, and/or ZnO), and the conductive channel(s) can be formed by any metals or alloys (such as Ta, Cu, Au, Pt, Ag, Ru, CoFe, and/or NiFe).

The spacer layer 206 is non-magnetic and depending on the conductivity of the spacer layer 206, the magnetic element 200 may be referred to as a giant magnetoresistance (GMR) magnetic element or a tunnel magnetoresistance (TMR) magnetic element. For example, when the spacer layer 206 comprises a conductive material, the magnetic element 200 (in particular, the free layer 204, the spacer layer 206, and the reference layer 202 ) functions as a spin valve. On the other hand, when the space layer 206 comprises a non-conductive insulating material, the magnetic element 200 (in particular, the free layer 204, the spacer layer 206, and the reference layer 202 ) functions as a magnetic tunnel junction (MTJ).

As described hereinbefore, the current confined layer 220 is disposed on the surface 205 of the free layer 204 facing away from the spacer layer 206. In embodiments, the current confined layer 220 may be disposed directly on the surface 205 of the free layer 204. In other embodiments, the current confined layer 220 may be disposed on the surface 205 of the free layer 205 whereby there exists one or more intermediate/intervening layers therebetween. For example, as will be described later according to exemplary embodiments of the present invention, a performance enhancement layer may be disposed on the current confined layer 220 (e.g., disposed between the current confined layer 220 and the free layer 204 ) for enhancing the performance of the magnetic element 200.

It will be understood by a person skilled in the art that the current confined layer 220 can be implemented in any magnetic element which uses spin transfer torque to control its states (i.e., high or low resistance states), and examples thereof will be described later below according to example embodiments of the present invention. The magnetic element 200 can also be implemented in any type of magnetic memory devices which uses spin transfer torque for writing data. It will also be understood by a person skilled in the art that the structure of the magnetic element 200 described is not limited to the configuration/orientation as shown in FIG. 2 (which may be referred to as a bottom pin magnetic element whereby the current confined layer 220 and the free layer 204 are disposed above or over the spacer layer 206, and the reference layer 202 is disposed below or under the spacer layer 206 ) and the configuration/orientation of the magnetic element 200 may for example be inverted or reversed (which may be referred to as a top pin magnetic element whereby the current confined layer 220 and the free layer 204 are disposed below or under the spacer layer 206, and the reference layer 202 is disposed above or over the spacer layer 206 ), as long as the current confined layer 220 is disposed on a surface of the free layer 204 facing away from the spacer layer 206. Furthermore, the present disclosure may describe embodiments of the magnetic element 200 which can be operable in various orientations, and it thus should be understood that any of the terms “top”, “bottom”, “base”, “down”, “sideways”, “downwards”, etc., when used in the description herein are used for convenience and to aid understanding of relative positions or directions, and not intended to limit the orientation of the magnetic element 200. It will also be understood by a person skilled in the art that schematic drawings of the magnetic elements shown in the Figures may not be drawn to scale, and that various lengths, sizes and regions may be exaggerated for clarity.

Accordingly, by providing the current confined layer 220 on the surface of the free layer 204 facing away from the spacer layer 206, the overall write current required to achieve spin transfer switching of the magnetization of the free layer 204 of the magnetic element 200 can be significantly reduced without undesirably affecting the performances of the magnetic element 200. As discussed in the background, although non-uniform current has been previously utilized/implemented to enhance the current switching efficiency of conventional magnetic elements, the manner in which the current confined layer is utilized/implemented in such conventional magnetic elements unavoidably negatively affects certain performances thereof. For example, in the case of the current confined layer being inserted between the free layer and the reference layer of a TMR memory device, the present inventor found that the TMR will be significantly reduced due to the signal shunting by the conductive channels. On the other hand, in the case of the current confined layer being inserted into the free layer, the present inventor found that the crystalline structure of the free layer will deteriorate, thus resulting in the free layer having poor magnetic properties. These exemplary problems associated with such conventional magnetic elements have not been previously identified and addressed successfully. In contrast, embodiments of the present invention advantageously identified and addressed the above problems while keeping the advantages of high current switching efficiency associated with the non-uniform current switching technique as described hereinbefore.

Although a current confinement layer has previously been inserted between the spacing layer and the free layer or between the spacing layer and the reference layer, such conventional approaches assume or are based on the understanding that the flow between the free layer and the reference layer must be confined during the transfer of electrons from the free layer to the reference layer, or in an opposite direction, in order for the desired effect of local enhancement of the current to take place. Against this conventional teaching, the present inventor surprisingly found that a current confinement layer placed just outside the core region (MTJ or spin-valve region) and in close proximity with the free layer can also achieve the desired effect of local current density enhancement, but without undesirably affecting the performances of the magnetic element. By leaving the core region unperturbed, the present approach avoids any of the drawback faced by conventional methods in which a layer is inserted within this core structure, such as degradation of output signal.

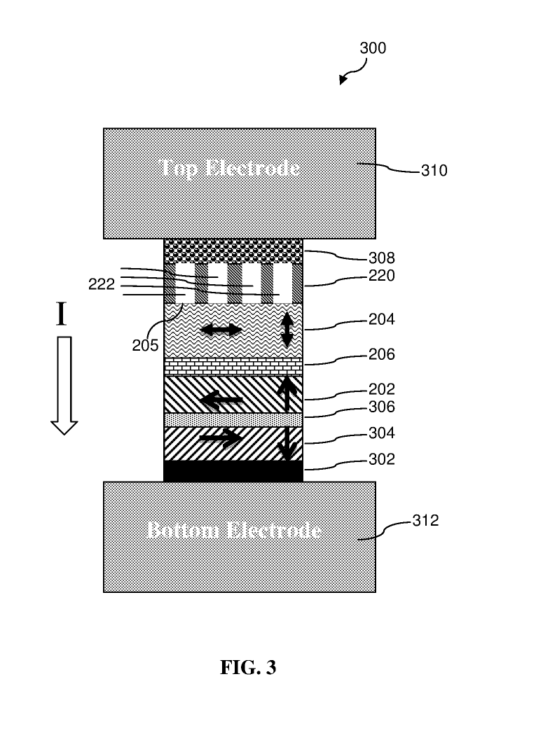

Hereinafter, the present invention will be described more fully with reference to FIGS. 3 to 6, in which example embodiments of the present invention are shown. This invention may, however, be embodied in many different forms and should not be construed as limited to the exemplary embodiments set forth herein. Rather, these embodiments are provided so that this disclosure will be thorough and complete, and will fully convey the scope of the invention to those skilled in the art.

FIG. 3 depicts a schematic drawing of an exemplary magnetic element 300 according to a first example embodiment of the present invention. The magnetic element 300 comprises a reference layer 202 made of a ferromagnetic material and having a fixed or pinned magnetization direction, a free layer 204 made of a ferromagnetic material and having a switchable magnetization direction based spin transfer torque, and a spacer layer 206 disposed between the reference layer 202 and the free layer 204 in the same manner as described with respect to FIG. 2. As shown in FIG. 3, the free layer 204 comprises a surface 205 facing away from the spacer layer 206, and the magnetic element 200 further comprises a current confined layer 220 disposed on the above-mentioned surface 205 of the free layer 204. In the example, the magnetic element 300 comprises an antiferromagnetic (AFM) layer 302, a pinned layer 304 having its magnetization direction pinned by the AFM layer 302, and an AFM coupling layer 306 for exchange coupling the reference layer 202 to the pinned layer 304 such that the magnetization direction of the reference layer 202 is pinned to that of the pinned layer 304 in an anti-parallel manner. The magnetic element 300 further comprises a capping layer 308 for functioning as a diffusion block. The above-mentioned layers of the magnetic element 300 may then be sandwiched between two contact members, such as a top electrode 310 and a bottom electrode 312, as shown in FIG. 3 for a current to be apply across the magnetic element 300.

In the example embodiment as shown in FIG. 3, the current confined layer 220 is disposed directly on the surface 205 of the free layer 204 facing away from the spacer layer 206. If the magnetic element 300 is oriented/configured as shown in FIG. 3 (which may be referred to as a bottom pin magnetic element), the current confined layer 220 can be considered to be directly on or over the top surface 205 of the free layer 204. However, for example, if the magnetic element 300 is oriented/configured in a reversed or an inverted manner to that shown in FIG. 3 (which may be referred to as a top pin magnetic element), it can be understood that the current confined layer can then be considered to be directly on or under the bottom surface of the free layer 204.

In the example embodiment, the current confined layer 220 comprises a plurality of conductive channels 222 in an insulating matrix such that the capping layer 308 (or the electrode 310 ) and the free layer 204 are conductively coupled through the plurality of conductive channels 222. In operation, when a current (I) is flowing through the magnetic element 300, the current will be concentrated to the conductive channels 222 of the current confined layer 220. Therefore, the localized current density of the portions/regions of the free layer 204 underneath the conductive channels 222 will be substantially larger than the other portions of the free layer 204. When this localized current density exceeds critical switching current density (Jc), the localized magnetization of the free layer 204 opposing the conductive channels 222 (i.e., the portions underneath the conductive channels in the example embodiment of FIG. 3) will switch first, and then in turn induce the switching of the entire free layer 204 due to the exchange coupling. Therefore, the overall current required for switching the entire free layer 204 is substantially reduced compared to the conventional uniform flow technique. It can be understood that the magnetic anisotropy in the magnetic element described herein can be either perpendicular to the plane or in the plane as illustrated in the drawings.

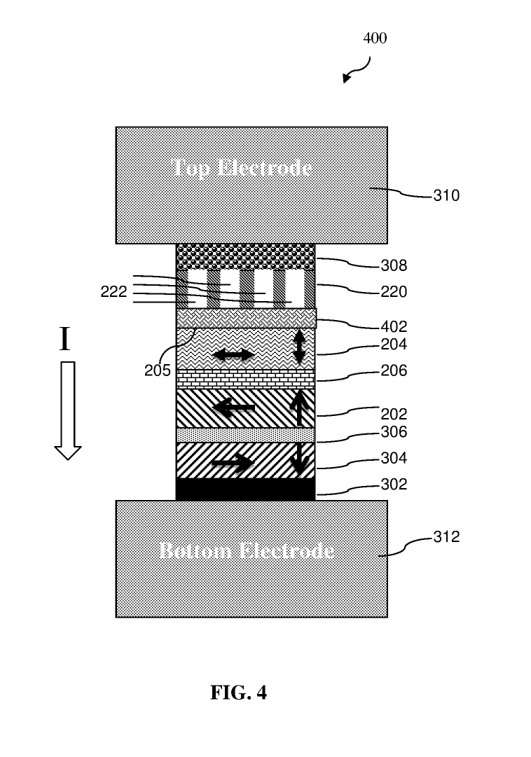

FIG. 4 depicts a schematic drawing of an exemplary magnetic element 400 according to a second example embodiment of the present invention. The magnetic element 400 is the same as the magnetic element 300 as illustrated in FIG. 3, except that a performance enhancement layer 402 is disposed on the free layer 204 (can also be considered as disposed on the current confined layer 220 ), between the free layer 204 and the current confined layer 220, for enhancing the performance of the magnetic element 400. Therefore, the description of the layers/elements of the magnetic element 400 which are the same or similar as the corresponding layers/elements of the magnetic element 300 described hereinbefore may not be repeated for clarity and conciseness. It can be understood that the same or similar layers/elements are denoted using the same reference numerals throughout the drawings.

In the example embodiment of FIG. 4, the performance enhancement layer 402 is preferably a conductive tuning layer for tuning the performance of the magnetic element 400. The conductive tuning layer 402 can be configured to perform a particular performance tuning function. For example, in the case of the free layer 204 being made of CoFeB, the conductive tuning layer 402 can be a metallic tuning layer (e.g., made of Ta, R, and/or Ti) used for B absorption to enhance crystalline structure of the free layer 204 and TMR characteristics. As another example, the conductive tuning layer 402 can be a magnetic tuning layer (e.g., made of a magnetic material such as MnGa) used as the magnetic anisotropy enhanced layer to improve or adjust the magnetic anisotropy of the free layer 204. As a further example, the conductive tuning layer 402 can also serve as a protection layer (e.g., made of Mg) to prevent the oxidation of the free layer 204 during the formation of the current confined layer 220 thereon. As yet another example, the conductive tuning layer 402 can serve as a crystalline structure control layer (e.g., made of Pt, Ta, Ru, and/or Ti) to promote/tune the desired crystalline structure of the free layer 204. It can be appreciated to a person skilled in the art that the performance enhancement layer 402 is not limited to the specific examples described above and other applicable types of performance enhancement layer are within the scope of the present invention.

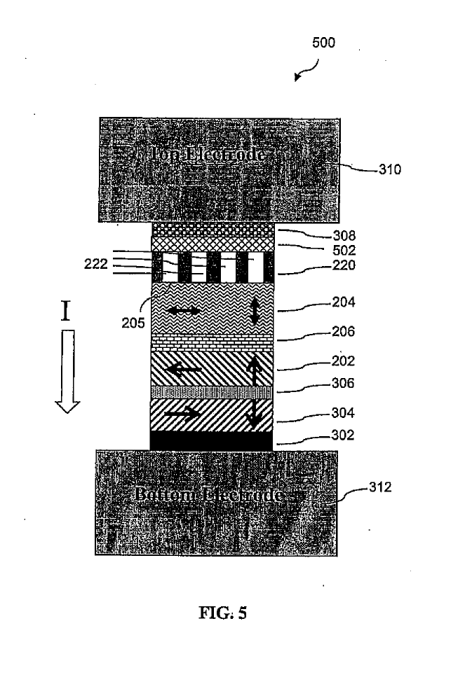

FIG. 5 depicts a schematic drawing of an exemplary magnetic element 500 according to a third example embodiment of the present invention. The magnetic element 500 is the same as the magnetic element 300 as illustrated in FIG. 3, except that a performance enhancement layer 502 is disposed on the current confined layer 220, between the current confined layer 220 and the capping layer 308 (or top electrode 310 ), for enhancing the performance of the magnetic element 500. Therefore, the description of the layers/elements of the magnetic element 500 which are the same or similar as the corresponding layers/elements of the magnetic element 300 described hereinbefore are not repeated for clarity and conciseness. In the example embodiment of FIG. 5, the performance enhancement layer 502 comprises a field cancellation layer disposed on the current confined layer 220 for providing offset field control.

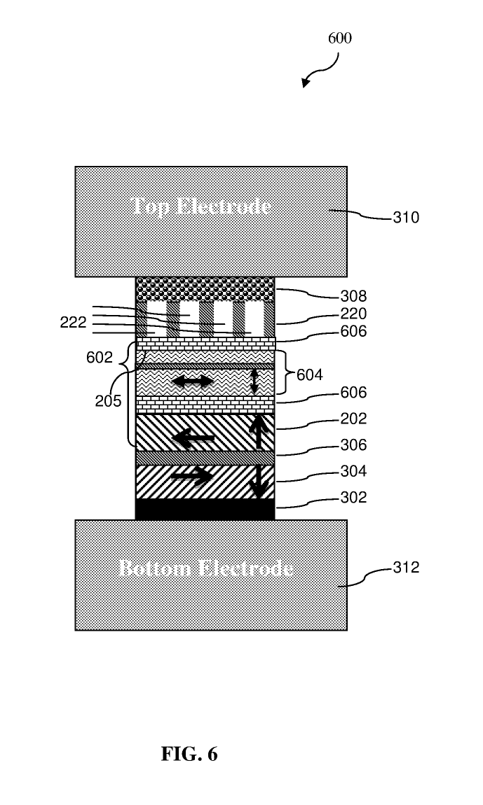

FIG. 6 depicts a schematic drawing of an exemplary magnetic element 600 according to a fourth example embodiment of the present invention. The magnetic element 600 is the same as the magnetic element 300 as illustrated in FIG. 3, except the magnetic element 600 comprises a double MgO barrier MTJ 602 as an example for enhanced perpendicular anisotropy and TMR ratio. In particular, the double MgO barrier MTJ 602 comprises two MgO layers 606 and a free layer 604 disposed therebetween. In this example, the free layer 604 is a CFB/Ta/CFB multi-layer, where CFB can be a CoFeB alloy. The Boron concentration may be between 12% and 25% and the (CoₓFe₁₋ₓ)_{y}B_{1-y} concentration may be such that × is between 20 and 80%.

It will be understood that the above magnetic elements as described with reference to FIGS. 3 to 6 are merely examples for illustration purposes only and the magnetic element according to the present invention is not limited to having such specific structures/configurations. It will be understand that the magnetic element according to the present invention can have any type of configuration/structure as suitable/appropriate, as long as the magnetic element is spin current driven and comprises the current confined layer 220 disposed/formed in the manner as described herein according to embodiments of the present invention.

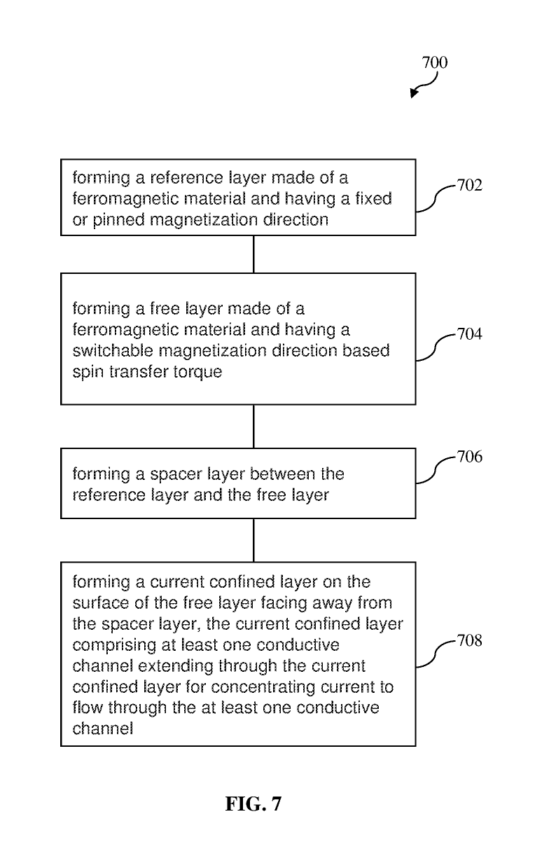

FIG. 7 depicts a flow diagram of a method 700 of fabricating a magnetic element according to an embodiment of the present invention. The method 700 comprises a step 702 of forming a reference layer 202 made of a ferromagnetic material and having a fixed or pinned magnetization direction, a step of 704 forming a free layer 204 made of a ferromagnetic material and having a switchable magnetization direction based spin transfer torque, and a step of 706 forming a spacer layer 206 between the reference layer 202 and the free layer 204. In particular, the free layer 204 comprises a surface 205 facing away from the spacer layer 206 and the method 700 further comprises a step 708 of forming a current confined layer 220 on the surface 205 of the free layer 204. The current confined layer 220 comprising at least one conductive channel 222 extending through the current confined layer 220 for concentrating current to flow through the at least one conductive channel 222. It will be understood that notwithstanding the order in which the above steps are described, the above steps can be performed in any order suitable for a desired end result. For example, for a magnetic element 200 made to have an orientation/orientation as shown in FIG. 2, it can be understood that the reference layer 202 may first be formed, followed by a spacer layer 206 formed on the reference layer 202, a free layer 204 formed on the spacer layer 206, and then the current confined layer 220 formed on the free layer 204.

It can be understood that a person skilled in the art would be able to apply appropriate/suitable deposition techniques and conditions known in the art to perform the above-mentioned steps in the method 700 of fabricating a magnetic element. Therefore, it is not necessary to describe the specific deposition techniques and conditions herein. For example, in relation to the current confined layer, it can be fabricated by depositing an oxide layer under an atmosphere leading to an oxygen deficient stoichiometry so that pinholes, i.e. paths of low resistivity spontaneously appear. The current confined layer could also be prepared by depositing an oxide layer in a three-dimensional growth mode and keeping the overall thickness of the oxide layer thin enough so that the three dimensional islands created during the growth do not fully coalesce. During the deposition of the subsequent electrode, the metal of the electrode would then enter the interstitial spaces between these islands, thus leading to paths of low resistivity in which the current would prefer to flow during the operation of the magnetic element.

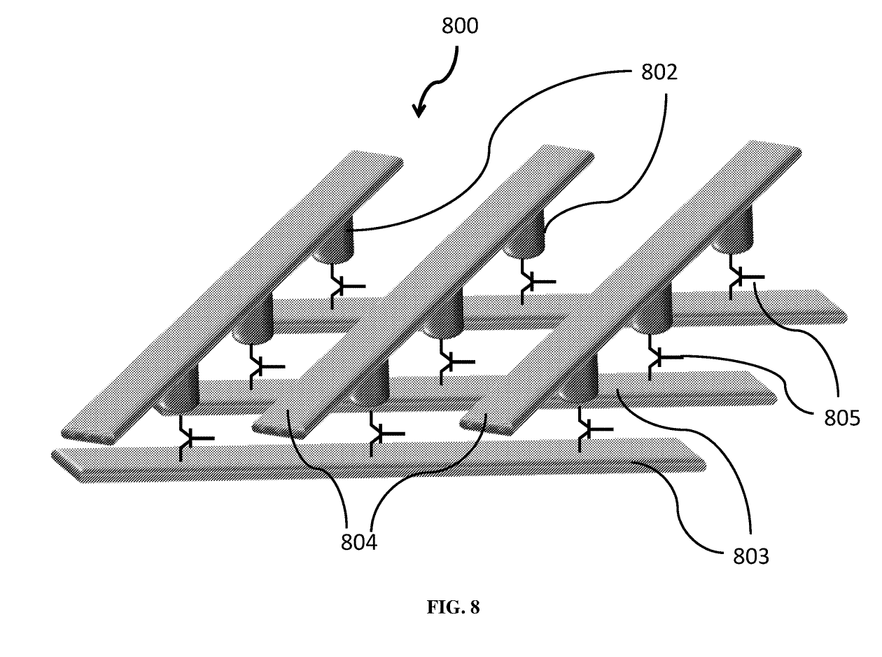

FIG. 8 depicts a schematic drawing of a magnetic memory device 800 according to an example embodiment for illustration purposes only. The magnetic memory device 800 comprises an array/grid of magnetic elements 802 described hereinbefore according to embodiments of the present invention and connected between word lines 803 and bit lines 804. As shown in FIG. 8, each magnetic element 802 may be coupled to the word line 803 via a transistor 805. The transistor 805 is operable to select the magnetic element 802 during the write process and the read process. As mentioned hereinbefore, the magnetic memory device 800 can be any magnetic memory device that is spin current driven, such as but not limited to, a STT-MRAM device.

Accordingly, embodiments of the present invention provide a simple yet effective approach of reducing the required write current to switch the magnetization of the free layer in a magnetic element using non-uniform current. More importantly, this is achieved without undesirably affecting (e.g., causing a negative impact on) the performances of the magnetic element in contrast to conventional magnetic elements such as those described in the background.

While embodiments of the invention have been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1.-19. (canceled)

20. A magnetic element comprising:
a reference layer made of a ferromagnetic material and having a fixed or pinned magnetization direction;
a free layer made of a ferromagnetic material and having a switchable magnetization direction based spin transfer torque;
a spacer layer disposed between the reference layer and the free layer,
wherein the free layer comprises a surface facing away from the spacer layer, and
the magnetic element further comprises:
a current confined layer disposed on said surface of the free layer, the current confined layer comprising at least one conductive channel extending through the current confined layer for concentrating current to flow through the at least one conductive channel, and
a conductive tuning layer disposed on the free layer so as to be between the free layer and the current confined layer, the conductive tuning layer configured to tune a crystalline structure or a magnetic anisotropy of the free layer for tuning a performance of the magnetic element.

21. The magnetic element according to claim 20, wherein said at least one conductive channel comprises a plurality of conductive channels extending through the current confined layer.

22. The magnetic element according to claim 20, wherein the current confined layer comprises an insulating matrix, and said at least one conductive channel is formed through the insulating matrix.

23. The magnetic element according to claim-20, wherein the spacer layer is non-magnetic and comprises a conductive material, and wherein the free layer, the spacer layer, and the reference layer are configured to function as a spin valve.

24. The magnetic element according to claim 20, wherein the spacer layer is non-magnetic and comprises a non-conductive insulating material, and wherein the free layer, the spacer layer, and the reference layer are configured to function as a magnetic tunnel junction.

25. The magnetic element according to claim 20, further comprises a field cancellation layer is disposed on the current confined layer for providing offset field control.

26. The magnetic element according claim 20, wherein the conductive tuning layer further serves as a protection layer for protecting the free layer when the current confined layer is being formed on the free layer.

27. The magnetic element according to claim 20, further comprises a capping layer disposed on the current confined layer, wherein the capping layer and the free layer are conductively coupled through said at least one conductive channel of the current confined layer.

28. A method of fabricating a magnetic element, the method comprising:
forming a reference layer made of a ferromagnetic material and having a fixed or pinned magnetization direction;
forming a free layer made of a ferromagnetic material and having a switchable magnetization direction based spin transfer torque;
forming a spacer layer between the reference layer and the free layer,
wherein the free layer comprises a surface facing away from the spacer layer, and
the method further comprises:
forming a current confined layer on said surface of the free layer, the current confined layer comprising at least one conductive channel extending through the current confined layer for concentrating current to flow through the at least one conductive channel, and
forming a conductive tuning layer on the free layer so as to be between the free layer and the current confined layer, the conductive tuning layer configured to tune a crystalline structure or a magnetic anisotropy of the free layer for tuning a performance of the magnetic element.

29. The method according to claim 28, wherein said at least one conductive channel comprises a plurality of conductive channels extending through the current confined layer.

30. The method according to claim 28, wherein the current confined layer comprises an insulating matrix, and said at least one conductive channel is formed through the insulating matrix.

31. The method according to claim 28, further comprises forming a field cancellation layer on the current confined layer for providing offset field control.

32. The method according to claim 28, wherein the conductive tuning layer further serves as a protection layer for protecting the free layer when the current confined layer is being formed on the free layer.

33. The method according to claim 28, further comprises forming a capping layer on the current confined layer, wherein the capping layer and the free layer are conductively coupled through said at least one conductive channel of the current confined layer.

34. A magnetic memory device comprising an array of magnetic elements, wherein each magnetic element comprising:
a reference layer made of a ferromagnetic material and having a fixed or pinned magnetization direction;
a free layer made of a ferromagnetic material and having a switchable magnetization direction based spin transfer torque;
a spacer layer disposed between the reference layer and the free layer,
wherein the free layer comprises a surface facing away from the spacer layer, and
the magnetic element further comprises:
a current confined layer disposed on said surface of the free layer, the current confined layer comprising at least one conductive channel extending through the current confined layer for concentrating current to flow through the at least one conductive channel, and
a conductive tuning layer disposed on the free layer so as to be between the free layer and the current confined layer, the conductive tuning layer configured to tune a crystalline structure or a magnetic anisotropy of the free layer for tuning a performance of the magnetic element.
